(19) United States
(12) Patent Application Publication
(10) Pub. No.: US 2026/0047084 A1
(43) Pub. Date: Feb. 12, 2026

(54) SEMICONDUCTOR DEVICE

(71) Applicant: Samsung Electronics Co., Ltd., Suwon-si (KR)

(72) Inventors: Gyunghyun Yoon, Suwon-si (KR); Youngwoo Kim, Suwon-si (KR)

(21) Appl. No.: 19/258,005

(22) Filed: Jul. 2, 2025

(30) Foreign Application Priority Data
Aug. 7, 2024 (KR) 10-2024-0105478

(51) Int. Cl. H10B 12/00

(52) U.S. Cl. CPC H10B 12/50; H10B 12/09; H10B 12/315

(57) ABSTRACT

A semiconductor device includes a device isolation region defining a cell active region and a peripheral active region on a substrate, a gate structure extending in a horizontal direction across the cell active region, extending into the device isolation region, and having an end surface within the device isolation region, and a gate contact plug contacting the gate structure, between the cell active region and the peripheral active region. A device isolation layer of the device isolation region includes a first insulating layer, a second insulating layer, and a buried insulating layer. A maximum distance in the horizontal direction between the end surface and a first portion on which the gate contact plug contacts the gate structure is substantially equal to or greater than a maximum distance between the end surface and a second portion on which the second insulating layer of the device isolation layer contacts the gate structure.

### CROSS-REFERENCE TO RELATED APPLICATION(S)

This application claims the benefit under 35 U.S.C. § 119(a) of Korean Patent Application No. 10-2024-0105478 filed on Aug. 7, 2024 in the Korean Intellectual Property Office, the entire disclosure of which is incorporated herein by reference for all purposes.

### BACKGROUND

The present inventive concept relates generally to a semiconductor device.

As the electronics industry develops and user demand increases, electronic devices are becoming smaller and more high-performance. Accordingly, semiconductor devices used in electronic devices are also required to be highly integrated and more powerful. To manufacture high-performance semiconductor devices, word lines are formed with narrower line widths, and word line disconnection defects are occurring.

### SUMMARY

Example embodiments provide a semiconductor device having improved electrical characteristics and reliability.

According to example embodiments, a semiconductor device includes: a substrate having a cell array region, a peripheral circuit region, and a connection region between the cell array region and the peripheral circuit region; a device isolation region including a cell device isolation region defining a cell active region on the cell array region and a connection device isolation region defining an active region on the connection region, on the substrate; a gate structure traversing the cell active region on the cell array region and including a gate electrode extending into the connection device isolation region of the device isolation region on the connection region; and a gate contact plug connected to the gate electrode, on the connection region, the gate contact plug having a first side facing the cell array region and a second side opposite the first side. The connection device isolation region includes a first insulating layer and a second insulating layer on the first insulating layer. The second insulating layer has a first side facing the cell array region and a second side facing the peripheral circuit region. A minimum distance between the cell array region and the first side of the gate contact plug is substantially equal to or less than a minimum distance between the cell array region and the first side of the second insulating layer.

According to example embodiments, a semiconductor device includes: a device isolation region defining a cell active region and a peripheral active region on a substrate; a gate structure traversing the cell active region in a horizontal direction parallel to an upper surface of the substrate, extending into the device isolation region, and having an end surface within the device isolation region; and a gate contact plug contacting the gate structure, between the cell active region and the peripheral active region. A device isolation layer of the device isolation region includes a first insulating layer, a second insulating layer on the first insulating layer, and a buried insulating layer on the second insulating layer. A maximum distance between the end surface and a first portion on which the gate contact plug and the gate structure contact, in the horizontal direction, is substantially equal to or greater than a maximum distance between the end surface and a second portion on which the second insulating layer of the device isolation layer contacts the gate structure, in the horizontal direction.

According to example embodiments, a semiconductor device includes: a substrate having a cell array region, a peripheral circuit region, and a connection region between the cell array region and the peripheral circuit region; a device isolation region including a cell device isolation region defining a cell active region of the cell array region and a connection device isolation region defining an active region on the connection region, on the substrate; a gate structure traversing the cell active region, on the cell array region, in a horizontal direction parallel to an upper surface of the substrate, and including a gate electrode extending into the connection device isolation region of the device isolation region on the connection region; and a gate contact plug connected to the gate electrode, on the connection region. The connection device isolation region includes a first insulating layer, a second insulating layer on the first insulating layer, and a buried insulating layer on the second insulating layer. A maximum distance between the active region on the connection region and a first portion on which the gate contact plug contacts the gate electrode, in the horizontal direction, is substantially equal to or greater than a maximum distance between the active region on the connection region and a second portion on which the second insulating layer contacts the gate electrode, in the horizontal direction.

### BRIEF DESCRIPTION OF DRAWINGS

The above and other aspects, features, and advantages of the present inventive concept will be more clearly understood from the following detailed description, taken in conjunction with the accompanying drawings, wherein like reference numerals (when used) indicate corresponding elements throughout the several views, and in which:

FIG. 1 is a schematic plan view of a semiconductor device according to example embodiments;

FIG. 2A is a schematic cross-sectional view of a semiconductor device according to example embodiments, and illustrates cross-sections of the semiconductor device of FIG. 1 taken along cut lines I-I′ and II-II′;

FIG. 2B is a schematic cross-sectional view of a semiconductor device according to example embodiments, and illustrates a cross-section of the semiconductor device of FIG. 1 taken along cut line III-III′;

FIG. 2C is a schematic cross-sectional view of a semiconductor device according to example embodiments, and illustrates a cross-section of the semiconductor device of FIG. 1 taken along cut line IV-IV′;

FIG. 3 is a partial enlarged cross-sectional view of a semiconductor device according to example embodiments, and an enlarged view of area ‘A’ including a contact plug of FIG. 2B;

FIG. 4, FIG. 5, FIG. 6, FIG. 7, and FIG. 8 are partial enlarged cross-sectional views of semiconductor devices according to example embodiments; and

FIGS. 9, 10, 11, 12, 13, and 14 are cross-sectional views illustrating intermediate processes in a method of manufacturing a semiconductor device according to example embodiments.

### DETAILED DESCRIPTION

Hereinafter, terms such as “on,” “upper,” “upper surface,” “below,” “lower,” “lower surface,” “side,” “side surface,” “top,” “bottom,” and the like are understood to refer to the drawings, except in cases where they are separately referred to by being indicated with drawing symbols. Terms such as “upper,” “middle,” “intermediate,” and “lower” may also be replaced with other terms, such as “first,” “second,” and “third,” and used to describe components of the specification. Ordinal terms such as “first,” “second,” and “third” may be used to describe various components, but the components are not limited by the terms, and a “first component” may be named a “second component; ” that is, such ordinal terms are not intended to convey to particular position or order to a given element or structure, unless the context indicates otherwise.

Hereinafter, example embodiments will be described with reference to the attached drawings.

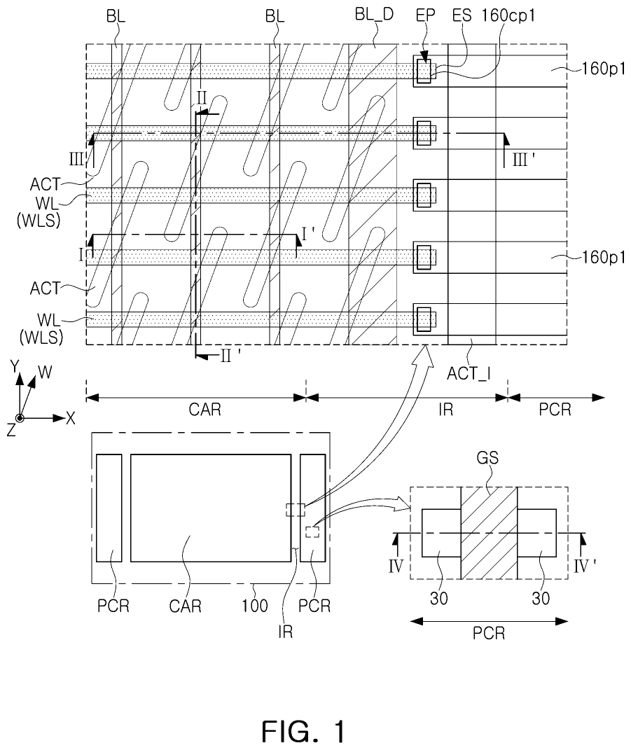

FIG. 1 is a schematic plan view of a semiconductor device according to example embodiments.

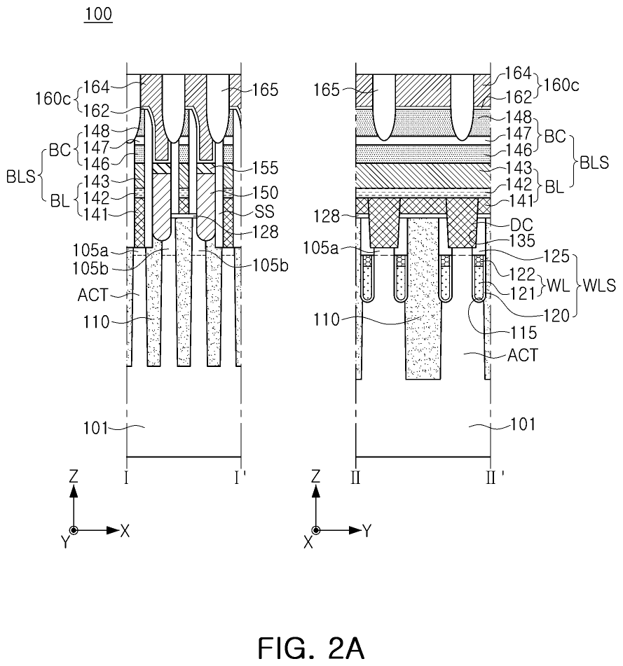

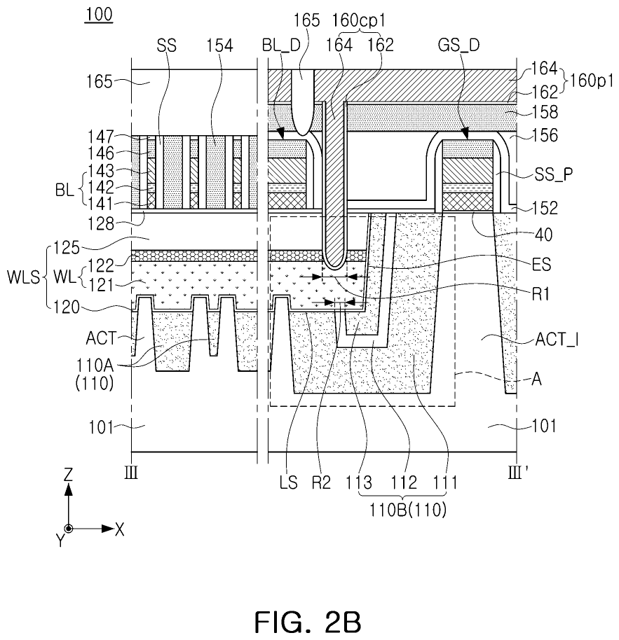

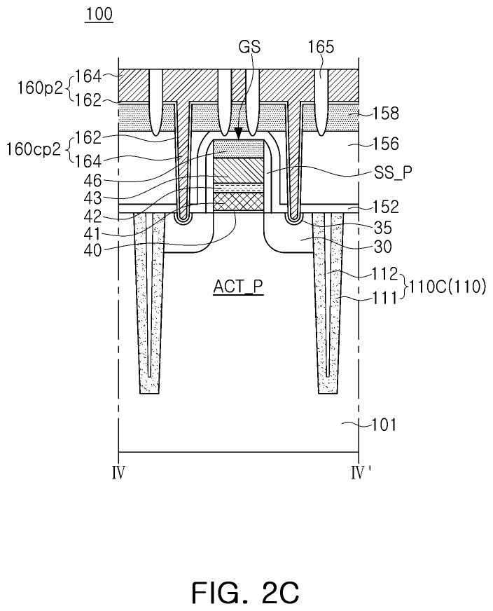

FIG. 2A is a schematic cross-sectional view of a semiconductor device according to example embodiments. FIG. 2A illustrates cross-sections of the semiconductor device of FIG. 1 along cut lines I-I′ and II-II′.

FIG. 2B is a schematic cross-sectional view of a semiconductor device according to example embodiments. FIG. 2B illustrates a cross-section of the semiconductor device of FIG. 1 along cut line III-III′.

FIG. 2C is a schematic cross-sectional view of a semiconductor device according to example embodiments. FIG. 2C illustrates a cross-section of the semiconductor device of FIG. 1 along cut line IV-IV′.

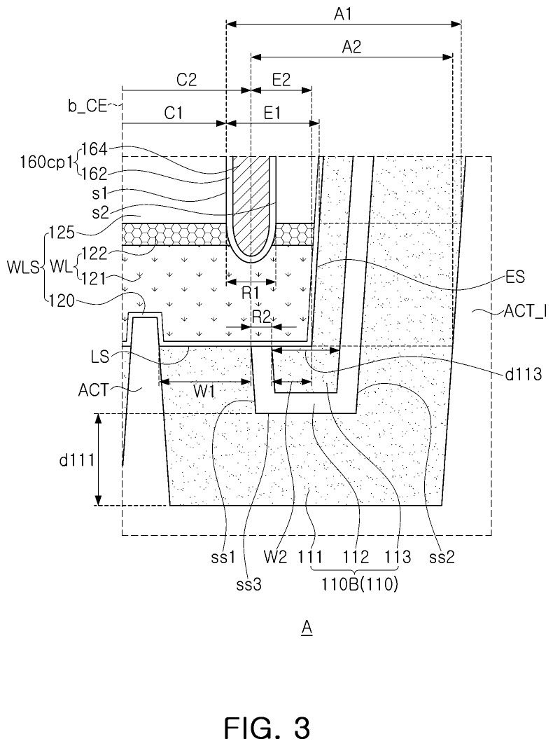

FIG. 3 is a partially enlarged cross-sectional view of a semiconductor device according to example embodiments. FIG. 3 is an enlarged view of area ‘A’ including a contact plug of FIG. 2B.

Referring to FIG. 1, a semiconductor device 100 may include a cell array region CAR, a peripheral circuit region PCR for driving the cell array region CAR, and a connection region IR between the cell array region CAR and the peripheral circuit region PCR. In the present specification, the regions CAR, PCR and IR may be defined and described in a substrate 101 (see FIGS. 2A-2C). The cell array region CAR may be a region in which memory cells are disposed. The peripheral circuit region PCR may be disposed around the cell array region CAR. The peripheral circuit region PCR may be a region in which a word line driver, a sense amplifier, row and column decoders, and control circuits are disposed, although embodiments are not limited thereto. The connection region IR may be a region for electrically connecting circuits and/or elements in the cell array region CAR and circuits and/or elements in the peripheral circuit region PCR to each other. For example, in the connection region IR, a word line WL may be connected to a gate contact plug 160cp1, and the gate contact plug 160cp1 may be connected to an upper conductive pattern 160p1. The term “connected” (or “connecting,” or like terms, such as “contact” or “contacting”), as may be used herein, is intended to refer to a physical and/or electrical connection between two or more elements, and may include other intervening elements. As used herein, the term “and/or” includes any and all combinations of one or more of the associated listed items.

Referring to FIGS. 1, 2A, 2B, 2C and 3, the semiconductor device 100 may include a substrate 101 including cell active regions ACT, a device isolation region 110 defining the cell active regions ACT within the substrate 101, one or more word line structures WLS buried and extending within the substrate 101, each word line structure including a word line WL, and one or more bit line structures BLS extending across the word line structure WLS, on the substrate 101, each bit line structure including a bit line BL. The cell active regions ACT, word line structures WLS, and bit line structures BLS may be disposed in the cell array region CAR.

The semiconductor device 100 may further include a lower conductive pattern 150 on the cell active region ACT, a first upper conductive pattern 160c on the lower conductive pattern 150, a gate contact plug 160cp1 connected to the word line WL in the connection region IR, a second upper conductive pattern 160p1 on the gate contact plug 160cp1, a peripheral contact plug 160cp2 connected to a peripheral source/drain region 30 in the peripheral circuit region PCR, a third upper conductive pattern 160p2 on the peripheral contact plug 160cp2, and one or more insulating patterns 165 penetrating (i.e., extending in) the upper conductive patterns 160c, 160p1 and 160p2 in a vertical (Z) direction perpendicular to an upper surface of the substrate 101.

The semiconductor device 100 may further include a peripheral transistor, an insulating liner 152, and interlayer insulating layers 156 and 158 disposed on the substrate 101 in the peripheral circuit region PCR, and the peripheral transistor may include a peripheral gate dielectric layer 40, peripheral circuit gate electrodes 41, 42 and 43, and a peripheral source/drain region 30.

The semiconductor device 100 may include, for example, a cell array of a Dynamic Random Access Memory (DRAM). For example, a bit line BL may be connected to a first impurity region 105a of a cell active region ACT, and a second impurity region 105b of the cell active region ACT may be electrically connected to a capacitor structure on the first upper conductive pattern 160c through lower and upper conductive patterns 150, 160c. Although not illustrated, the capacitor structure may include, for example, a lower electrode, a capacitor dielectric layer, and an upper electrode, and the structure thereof is not particularly limited.

The substrate 101 may include a semiconductor material, such as a group IV semiconductor, a group III-V compound semiconductor, or a group II-VI compound semiconductor. For example, the group IV semiconductor may include silicon, germanium, or silicon-germanium. The substrate 101 may further include impurities. The substrate 101 may be a silicon substrate, a silicon-on-insulator (SOI) substrate, a germanium substrate, a germanium-on-insulator (GOI) substrate, a silicon-germanium substrate, or a substrate including an epitaxial layer, although embodiments are not limited thereto.

The cell active regions ACT may be defined within the substrate 101 by the device isolation region 110. The cell active regions ACT may be in the form of a bar and may be disposed in an island shape extending in one direction, for example, in the W direction, within the substrate 101. The W direction may be an inclined direction with respect to the extension direction of the word lines WL and the bit lines BL and parallel to the upper surface of the substrate 101. The cell active regions ACT may be arranged to be parallel to each other, and an end portion of one cell active region ACT may be arranged to be adjacent to the center of another cell active region ACT adjacent thereto.

The cell active region ACT may have first and second impurity regions 105a and 105b at a predetermined depth in the vertical (Z) direction, relative to the upper surface of the substrate 101 as a reference layer. The first and second impurity regions 105a and 105b may be spaced apart from each other in a first horizontal direction (X direction) parallel to the upper surface of the substrate 101. The first and second impurity regions 105a and 105b may be provided as source/drain regions of a transistor configured by a word line WL. For example, a drain region may be formed between two word lines WL crossing one cell active region ACT, and a source region may be respectively formed outside of the two word lines WL. The source region and the drain region are formed by the first and second impurity regions 105a and 105b by doping or ion implantation of substantially the same impurities, and may be referred to interchangeably depending on the circuit configuration of the transistor to be finally formed. The impurities may include dopants having a conductivity type opposite to that of the substrate 101. In example embodiments, the depths of the first and second impurity regions 105a and 105b in the source region and the drain region may be different from each other.

The device isolation region 110 may be formed by a shallow trench isolation (STI) process. The device isolation region 110 may surround and electrically isolate the cell active regions ACT from each other. The term “surround” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles. The device isolation region 110 may be formed of an insulating material, for example, silicon oxide, silicon nitride, or a combination thereof. The device isolation region 110 may include a plurality of regions having different bottom depths depending on the width of the trench in which the substrate 101 is etched.

The device isolation region 110 may include a cell device isolation region 110A defining a cell active region ACT, on the cell array region CAR, a connection device isolation region 110B defining an active region ACT_I, on the connection region IR, and a peripheral device isolation region 110C defining a peripheral active region ACT_P on the peripheral circuit region PCR.

The active region ACT_I may protrude (i.e., extend) in the Z direction from the substrate 101. The active region ACT_I may extend in a second direction (Y) parallel to the upper surface of the substrate 101 and perpendicular to the first direction (X) in which the word line WL extends between the connection device isolation regions 110B. The upper surface of the active region ACT_I may be disposed at substantially the same level as the upper surface of the gate capping layer 125, relative to the upper surface of the substrate 101 as a reference layer; that is, the upper surface of the active region ACT_I and the upper surface of the gate capping layer 125 may be coplanar. The upper surface of the active region ACT_I may be disposed at substantially the same level as the uppermost surface of the second insulating layer 112 and the uppermost surface of a buried insulating layer 113. A dummy gate structure GS_D may be disposed on the active region ACT_I, but is not limited thereto. On the connection region IR, the device isolation region 110 may include a plurality of layers, and for example, the connection device isolation region 110B may include a first insulating layer 111, a second insulating layer 112, and a buried insulating layer 113 in a region adjacent to an end portion EP of a word line WL, as illustrated in FIG. 2B. The second insulating layer 112 may be disposed on the first insulating layer 111, and the buried insulating layer 113 may be disposed on the second insulating layer 112. A first insulating layer 111 and a second insulating layer 112 may be sequentially formed conformally along a surface of the trench in an etched trench of a substrate 101 in which a connection device isolation region 110B is disposed. The term “conformally” (or “conformal,” or like terms), as may be used herein in the context of a material layer or coating, is intended to refer broadly to a material layer or coating having a substantially uniform cross-sectional thickness relative to the contour of a surface to which the material layer is applied. The first insulating layer 111 may be formed conformally along a surface of the trench with, for example, a first thickness d111 in the vertical (Z) direction. The buried insulating layer 113 may fill a space that the first and second insulating layers 111 and 112 do not fill in the trench. The term “fill” (or “filling,” “filled,” or like terms), as may be used herein, is intended to refer broadly to either completely filling a defined space (e.g., the trench) or partially filling the defined space; that is, the defined space need not be entirely filled but may, for example, be partially filled or have voids or other spaces throughout. The first thickness d111 may be substantially equal to or greater than a maximum thickness d113 of the buried insulating layer 113 in the first direction (X). The second insulating layer 112 may include an insulating material different from that of the first insulating layer 111, and the buried insulating layer 113 may include an insulating material different from that of the second insulating layer 112. For example, the first insulating layer 111 and the buried insulating layer 113 may include silicon oxide, and the second insulating layer 112 may include silicon nitride.

The lower surface of the connection device isolation region 110B may be located at a lower level than the lower surface of the cell device isolation region 110A, relative to the upper surface of the substrate 101 as a reference layer. For example, the lower surface of the first insulating layer 111 may be located at a lower level than the lower surface of the cell device isolation region 110A. Meanwhile, the lower surface of the second insulating layer 112 may be located at a higher level than the lower surface of the cell device isolation region 110A.

The word line structures WLS may be disposed within gate trenches 115 extending within the substrate 101. Each of the word line structures WLS may include a gate dielectric layer 120, a word line WL, and a gate capping layer 125. In this specification, ‘gate (120, WL)’ may be referred to as a structure including a gate dielectric layer 120 and a word line WL, the word line WL may be referred to as a ‘gate electrode’, and the word line structure WLS may be referred to as a ‘gate structure’. The word line structures WLS may cross the cell active region ACT, on the cell array region CAR, and may extend into the connection device isolation region 110B of the device isolation region 110 on the connection region IR.

The word line WL may extend in the first direction (X) across the cell active region ACT. For example, a pair of word lines WL adjacent to each other may be disposed to cross one cell active region ACT. The word line WL may form a gate of a BCAT (buried channel array transistor), but is not limited thereto. In example embodiments, the word lines WL may also have a form disposed on the upper side of the substrate 101. The word lines WL may be disposed on the lower side of the gate trench 115 with a predetermined thickness. The upper surface of the word lines WL may be located at a level lower than the upper surface of the substrate 101. In this specification, the high and low of the term “level” used may be defined based on the substantially flat upper surface of the substrate 101.

The word lines WL may include at least one of a conductive material, for example, polycrystalline silicon (Si), titanium (Ti), titanium nitride (TiN), tantalum (Ta), tantalum nitride (TaN), tungsten (W), tungsten nitride (WN), or aluminum (Al). For example, the word line WL may include a lower pattern 121 and an upper pattern 122 formed of different materials.

For example, the lower pattern 121 may include at least one of tungsten (W), titanium (Ti), tantalum (Ta), tungsten nitride (WN), titanium nitride (TiN), or tantalum nitride (TaN). For example, the upper pattern 122 may be a semiconductor pattern including polysilicon doped with P-type or N-type impurities, and the lower pattern 121 may be a metal pattern including at least one of a metal or a metal nitride. The thickness of the lower pattern 121 may be thicker than the thickness of the upper pattern 122. The lower pattern 121 and the upper pattern 122 may respectively extend in the first direction (X).

The gate dielectric layer 120 may be disposed on the bottom surface and inner side surfaces of the gate trench 115. The gate dielectric layer 120 may conformally cover the inner sidewall of the gate trench 115. The term “cover” (or “covers,” or like terms), as may be used herein, is intended to broadly refer to an element, structure or layer that is on or over another element, structure or layer, either directly or with one or more other intervening elements, structures or layers therebetween. The gate dielectric layer 120 may include at least one of silicon oxide, silicon nitride, or silicon oxynitride. The gate dielectric layer 120 may be, for example, a silicon oxide film or an insulating film having a high dielectric constant. In example embodiments, the gate dielectric layer 120 may be a layer formed by oxidizing the cell active region ACT or a layer formed by deposition.

The gate capping layer 125 may be disposed to fill the gate trench 115, on the word line WL. The upper surface of the gate capping layer 125 may be located at substantially the same level as the upper surface of the substrate 101; that is, the upper surface of the gate capping layer 125 and the upper surface of the substrate 101 may be coplanar. The gate capping layer 125 may be formed of an insulating material such as, for example, silicon nitride.

The bit line structure BLS may extend in one direction, for example, the Y-direction, perpendicular to the word line WL. The bit line structure BLS may include a bit line BL and a bit line capping pattern BC on the bit line BL. The bit line structure BLS may be disposed on the cell array region CAR, and a dummy bit line structure BL_D having a larger width in the X-direction than the bit line structure BLS may be disposed in the connection region IR. The dummy bit line structure BL_D may have a structure similar to the bit line structure BLS except that it has a relatively large width.

The bit line BL may include a first conductive pattern 141, a second conductive pattern 142, and a third conductive pattern 143 that are sequentially stacked in the Z-direction. The bit line capping pattern BC may be disposed on the third conductive pattern 143. A buffer insulating layer 128 may be disposed between the first conductive pattern 141 and the substrate 101, and a portion (hereinafter, referred to as a bit line contact pattern DC) of the first conductive pattern 141 may be in contact with the first impurity region 105a of a cell active region ACT. The bit line BL may be electrically connected to the first impurity region 105a through the bit line contact pattern DC. A lower surface of the bit line contact pattern DC may be located at a lower level, in the Z-direction, than an upper surface of the substrate 101 and may be located at a higher level than an upper surface of the word line WL. In an example embodiment, a bit line contact pattern DC may be locally positioned within a bit line contact hole 135 formed within the substrate 101 to expose a first impurity region 105a. The term “expose” (or “exposed,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device.

The first conductive pattern 141 may include a semiconductor material such as polycrystalline silicon. The first conductive pattern 141 may be in direct contact with the first impurity region 105a. The second conductive pattern 142 may include a metal-semiconductor compound. The metal-semiconductor compound may be, for example, a layer that silicides a portion of the first conductive pattern 141. For example, the metal-semiconductor compound may include cobalt silicide (CoSi), titanium silicide (TiSi), nickel silicide (NiSi), tungsten silicide (WSi), or other metal silicides. The third conductive pattern 143 may include a metal material such as titanium (Ti), tantalum (Ta), tungsten (W), and aluminum (Al), although embodiments are not limited thereto. The number of conductive patterns forming the bit line BL, the type of material, and/or the stacking order may vary depending on example embodiments.

The bit line capping pattern BC may include a first capping pattern 146, a second capping pattern 147, and a third capping pattern 148 sequentially stacked on the third conductive pattern 143 in the Z-direction. The first to third capping patterns 146, 147 and 148 may each include an insulating material, for example, a silicon nitride film. The first to third capping patterns 146, 147 and 148 may be formed of different materials, and even if the first to third capping patterns 146, 147 and 148 include the same material, the boundaries therebetween may be distinguished due to differences in physical properties. The thickness of the second capping pattern 147 in the Z-direction may be smaller than the thickness of the first capping pattern 146 and the thickness of the third capping pattern 148 in the Z-direction. The number of capping patterns and/or the type of material forming the bit line capping pattern BC may vary depending on embodiments.

A spacer structures SS may be disposed on both sidewalls of each of the bit line structures BLS and may extend in one direction, for example, the Y-direction. The spacer structures SS may be disposed between the bit line structure BLS and the lower conductive pattern 150. The spacer structures SS may be disposed to extend along the sidewalls of the bit line BL and the sidewalls of the bit line capping pattern BC. A pair of spacer structures SS disposed on both sides of one bit line structure BLS may have an asymmetrical shape with respect to the bit line structure BLS. Each of the spacer structures SS may include a plurality of spacer layers and, in some embodiments, may further include an air spacer.

The lower conductive pattern 150 may be connected to one region of the cell active region ACT, for example, the second impurity region 105b. The lower conductive pattern 150 may be disposed between the bit lines BL and between the word lines WL. The lower conductive pattern 150 may penetrate the buffer insulating layer 128 and be connected to the second impurity region 105b of the cell active region ACT. The lower conductive pattern 150 may be in direct contact with the second impurity region 105b. The lower surface of the lower conductive pattern 150 may be located at a level lower than the upper surface of the substrate 101 and may be located at a level higher than the lower surface of the bit line contact pattern DC. The lower conductive pattern 150 may be insulated from the bit line contact pattern DC by the spacer structure SS. The lower conductive pattern 150 may be formed of a conductive material, and may include at least one of, for example, polycrystalline silicon (Si), titanium (Ti), titanium nitride (TiN), tantalum (Ta), tantalum nitride (TaN), tungsten (W), tungsten nitride (WN), or aluminum (Al). In an example embodiment, the lower conductive pattern 150 may include a plurality of layers.

A metal-semiconductor compound layer 155 may be disposed between the lower conductive pattern 150 and the first upper conductive pattern 160c. The metal-semiconductor compound layer 155 may be, for example, a layer that silicides a portion of the lower conductive pattern 150 when the lower conductive pattern 150 includes a semiconductor material. The metal-semiconductor compound layer 155 may include, for example, cobalt silicide (CoSi), titanium silicide (TiSi), nickel silicide (NiSi), tungsten silicide (WSi), or other metal silicides. According to some embodiments, the metal-semiconductor compound layer 155 may be omitted.

The first upper conductive pattern 160c may be disposed on the lower conductive pattern 150 in the cell array region CAR. The first upper conductive pattern 160c may extend between the spacer structures SS to cover the upper surface of the metal-semiconductor compound layer 155. The second and third upper conductive patterns 160p1 and 160p2 may be disposed on the connection region IR and the peripheral circuit region PCR. Respective upper surfaces of the first to third upper conductive patterns 160c, 160p1 and 160p2 may be disposed at substantially the same level. The upper conductive patterns 160c, 160p1 and 160p2 may each include a barrier layer 162 and a conductive layer 164. The barrier layer 162 may cover a lower surface and side surfaces of the conductive layer 164. The barrier layer 162 may include at least one of a metal nitride, for example, titanium nitride (TiN), tantalum nitride (TaN), or tungsten nitride (WN). The conductive layer 164 may include at least one of a conductive material, for example, polycrystalline silicon (Si), titanium (Ti), tantalum (Ta), tungsten (W), ruthenium (Ru), copper (Cu), molybdenum (Mo), platinum (Pt), nickel (Ni), cobalt (Co), aluminum (Al), titanium nitride (TiN), tantalum nitride (TaN), or tungsten nitride (WN).

The gate contact plug 160cp1 may be provided in the connection region IR. In the connection region IR, the gate contact plug 160cp1 may be connected to the end portion EP of a word line WL (or a word line structure WLS).

The end portion EP of the word line WL or the end portion EP of the word line structure WLS may be disposed on the second device isolation region 110B covering the sidewall of the cell active region ACT adjacent thereto. For example, the end portion EP of the word line WL may be disposed on the second device isolation region 110B including the first insulating layer 111, the second insulating layer 112, and the buried insulating layer 113. The end portion EP of the word line structure WLS may provide an end surface ES exposed in the extension direction of the word line structure WLS, for example, the first direction (X). The end surface ES of the word line structure WLS may be a side surface of the gate dielectric layer 120. In the connection region IR, the end surface ES of the word line structure WLS may be located within the buried insulating layer 113.

From a first perspective, the arrangement relationship between the gate contact plug 160cp1 and the second insulating layer 112 may be defined from the perspective of the area where the gate contact plug 160cp1 contacts the word line WL and the area where the second insulating layer 112 contacts the word line structure WLS.

The region where the gate contact plug 160cp1 contacts the word line WL may be referred to as the first region R1. The first region R1 may be defined as the region where the gate contact plug 160cp1 contacts the upper pattern 122 and the lower pattern 121 of the word line WL. According to an example embodiment, the first region R1 may be referred to as the first portion R1.

The region where the second insulating layer 112 contacts the word line structure WLS may be referred to as the second region R2. According to an example embodiment, the second region R2 may be referred to as the second portion R2.

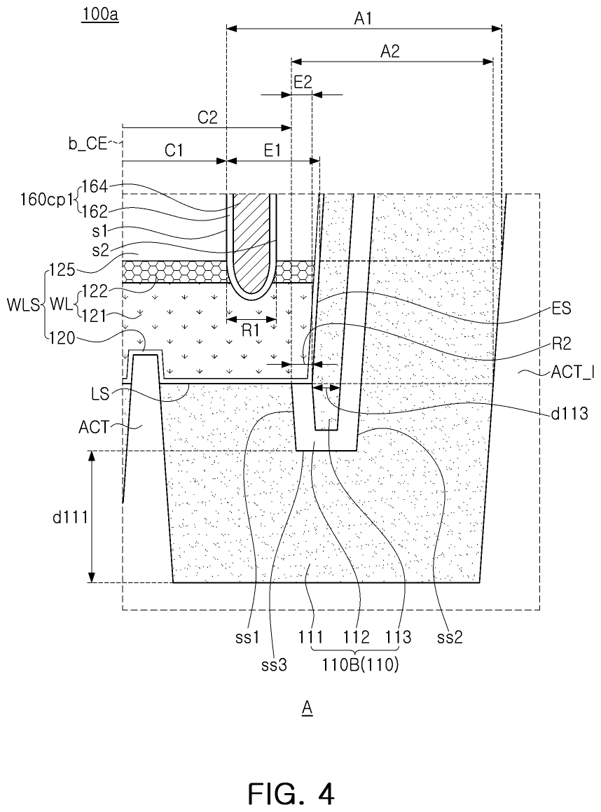

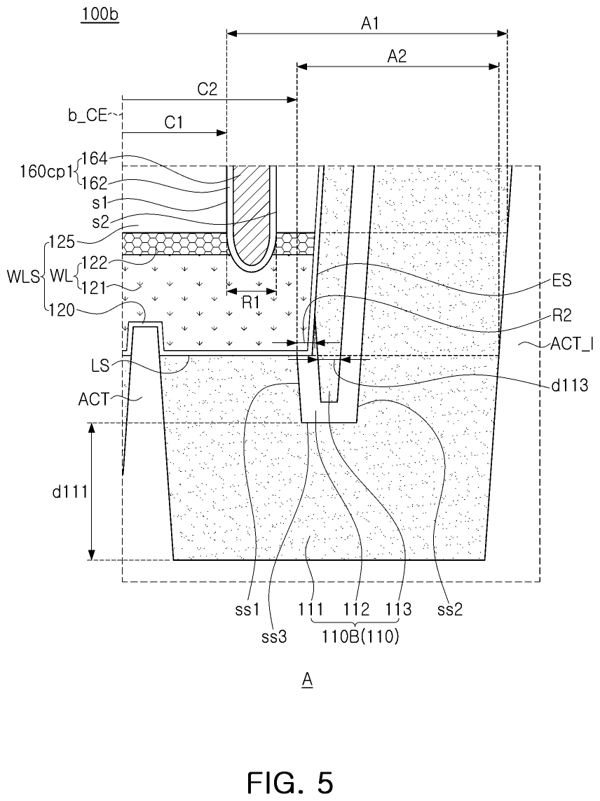

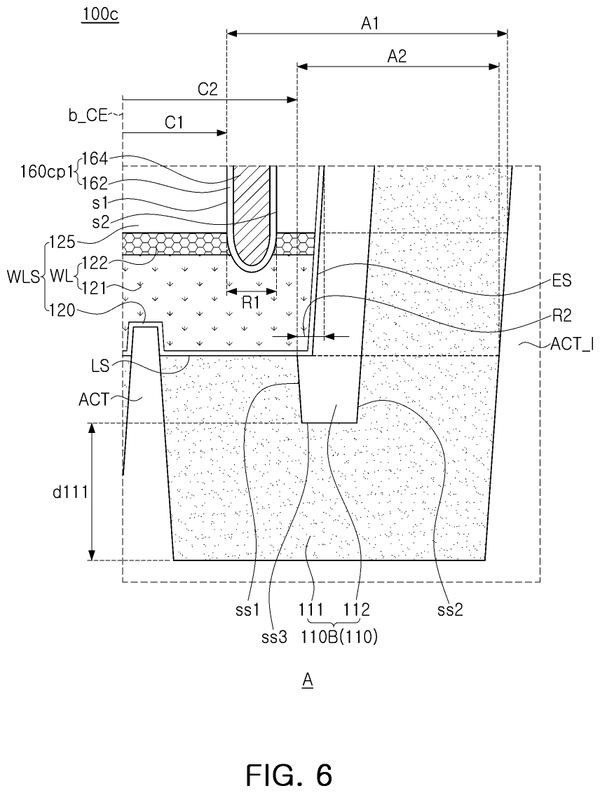

The second region R2 may be disposed close to the end portion EP of the word line structure WLS, for example, the end surface ES of the word line structure WLS. Accordingly, the second region R2 may overlap at least a portion of the first region R1 in the Z-direction, below the first region R1. As used herein, “an element A overlapping an element B in a direction X” (or similar language) means that there is at least one line that extends in the direction X and intersects both the elements A and B. In another embodiment, the second region R2 may be disposed so as not to overlap the first region R1 (see FIG. 4). In this case, the second region R2 may be disposed closer to the end surface ES of the word line structure WLS than the first region R1. The second region R2 may overlap at least a portion of the first region R1 in the Z-direction or may be disposed closer to the end portion EP of the word line structure WLS than the first region R1, thereby preventing a defect in which the word line WL is disconnected.

The arrangement relationship of the first and second regions R1 and R2 may be defined based on a boundary b_CE between the cell array region CAR and the connection region IR. In this case, the boundary b_CE may be a boundary between the cell array region CAR and the connection region IR, and may be defined as a virtual boundary line (or a virtual boundary surface extending in the Y- and Z-directions) between the bit line BL closest to the connection region IR and the dummy bit line structure BL_D adjacent to the cell array region CAR. A minimum distance C1 in the first direction (X) between the boundary b_CE and the first region R1 may be substantially equal to or less than a minimum distance C2 in the first direction (X) between the boundary b_CE and the second region R2.

From another perspective, the arrangement relationship of the first and second regions R1 and R2 may be defined based on the end surface ES of the word line structure WLS. A maximum distance E1 in the first direction (X) between the end surface ES and the first region R1 may be substantially equal to or greater than a maximum distance E2 in the first direction (X) between the end surface ES and the second region R2.

From another perspective, the arrangement relationship of the first and second regions R1 and R2 may be defined based on the active region ACT_I. A maximum distance A1 in the first direction (X) between the active region ACT_I and the first region R1 may be substantially equal to or greater than a maximum distance A2 in the first direction (X) between the active region ACT_I and the second region R2.

The gate contact plug 160cp1 may have a plurality of sides s1 and s2, and there may be a plurality of sides ss1, ss2 and ss3 of the second insulating layer 112 of the device isolation layer 110, as shown in FIG. 3.

In the cross-sectional view, the gate contact plug 160cp1 may have a first side s1 facing the cell array region CAR and a second side s2 opposite to the first side s1. The second side s2 may be the opposite side to the first side s1 with respect to the first direction (X).

In the cross-sectional view, the second insulating layer 112 may have a first side ss1 facing the cell array region CAR, a second side ss2 opposite to the first side ss1 and facing the peripheral circuit region PCR, and a third side ss3 physically connecting the first side ss1 and the second side ss2. The first side ss1 may be a side portion that is most adjacent to the cell array region CAR and is in contact with at least a portion of the first insulating layer 111, and the second side ss2 may be a side portion that is most adjacent to the peripheral circuit region PCR and is in contact with at least a portion of the first insulating layer 111. The third side ss3 may be the lower surface of the second insulating layer 112.

From a second perspective, the arrangement relationship between the gate contact plug 160cp1 and the second insulating layer 112 may be defined by the first and second sides s1 and s2 of the gate contact plug 160cp1 and the first side ss1 of the second insulating layer 112.

The minimum distance C1 between the cell array region CAR and the first side s1 of the gate contact plug 160cp1 may be substantially equal to or smaller than the minimum distance C2 between the cell array region CAR and the first side ss1 of the second insulating layer 112. In an example, the minimum distances C1 and C2 may be substantially equal to each other, and in this case, in the vertical direction (Z), the first side s1 of the gate contact plug 160cp1 and the first side ss1 of the second insulating layer 112 may be aligned. In another example, the minimum distance C1 is smaller than the minimum distance C2, and in the vertical direction (Z), the first side ss1 of the second insulating layer 112 may be located between the first and second sides s1, s2 of the gate contact plug 160cp1. In another example, the minimum distance C1 is smaller than the minimum distance C2, and the first side ss1 of the second insulating layer 112 may be spaced apart from the gate contact plug 160cp1 in the X-direction (see FIG. 4).

From another perspective, the maximum distance E1 may be defined as the maximum distance in the first direction (X) between the first side s1 of the gate contact plug 160cp1 and the end surface ES. The maximum distance E2 may be defined as the maximum distance in the first direction (X) between the first side ss1 of the second insulating layer 112 and the end surface ES. The maximum distance E1 may be substantially equal to or greater than the maximum distance E2.

In another aspect, the maximum distance A1 may be defined as the maximum distance in the first direction (X) between the first side s1 of the gate contact plug 160cp1 and the active region ACT_I. The maximum distance A2 may be defined as the maximum distance in the first direction (X) between the first side ss1 of the second insulating layer 112 and the active region ACT_I. The maximum distance A1 may be substantially equal to or greater than the maximum distance A2.

A lower surface LS of the word line structure WLS may be in contact with the first insulating layer 111 and the buried insulating layer 113. The buried insulating layer 113 may be in contact with the end surface ES of the word line structure WLS, and at least a portion of the buried insulating layer 113 may extend onto the lower surface LS of the word line structure WLS. The horizontal width in the first direction (X) of the portion where the lower surface LS of the word line structure WLS and the first insulating layer 111 are in contact may be defined as a first width W1, and the horizontal width in the first direction (X) of the portion where the lower surface LS of the word line WL and the buried insulating layer 113 are in contact may be defined as a second width W2. The first width W1 may be substantially equal to or larger than the second width W2.

The contact plug 160cp1 may have a long axis in the first direction (X) in a plane. For example, the contact plug 160cp1 may have a long bar shape in the first direction (X). For example, the contact plug 160cp1 may have a long oval shape in the first direction (X).

The contact plug 160cp1 may include a barrier layer 162 and a conductive layer 164. The contact plug 160cp1 may be connected to the second upper conductive pattern 160p1 and may be integral with the second upper conductive pattern 160p1. The contact plug 160cp1 may be completely overlapped with the second upper conductive pattern 160p1 in the vertical direction (Z).

The peripheral contact plug 160cp2 may be connected to the peripheral source/drain regions 30 by penetrating the first and second interlayer insulating layers 156 and 158 and the insulating liner 152 in the peripheral circuit region PCR. A peripheral metal-semiconductor compound layer 35 may be disposed between the peripheral contact plug 160cp2 and the peripheral source/drain regions 30. The peripheral contact plug 160cp2 may be connected to the third upper conductive pattern 160p2 and may be integral with the third upper conductive pattern 160p2.

The insulating patterns 165 may penetrate (i.e., extend in) the upper conductive patterns 160c, 160p1 and 160p2 in the vertical (Z) direction. The upper conductive patterns 160c, 160p1 and 160p2 may be separated into a plurality of pieces by insulating patterns 165. The insulating patterns 165 may include at least one of an insulating material, for example, silicon oxide, silicon nitride, and silicon oxynitride.

A peripheral gate structure GS may be disposed on a peripheral active region ACT_P in a peripheral circuit region PCR. The peripheral gate structure GS may include the peripheral gate dielectric layer 40, peripheral circuit gate electrodes 41, 42 and 43, and a peripheral gate capping layer 46 that are sequentially stacked in the vertical (Z) direction. An insulating liner 152 may cover the peripheral gate structure GS. The peripheral active region ACT_P may be defined by a peripheral device isolation region 110C, and the peripheral device isolation region 110C may include a first insulating layer 111 and a second insulating layer 112 that include different materials, but is not limited thereto. The peripheral gate dielectric layer 40 may include silicon oxide, silicon nitride, or a high dielectric constant (high-k) material. The high-k material may mean a dielectric material having a higher dielectric constant than silicon oxide. The peripheral circuit gate electrodes 41, 42 and 43 may be formed of a structure and material similar to the bit line BL, but may have a shape wider than the bit line BL.

FIGS. 4, 5, 6, 7, and 8 are partial enlarged cross-sectional views of semiconductor devices according to example embodiments. FIGS. 4, 5, 6, 7 and 8 illustrate various arrangements of region A shown in FIG. 3, according to embodiments of the present disclosure.

Referring to FIG. 4, a semiconductor device 100a of the modified embodiment may be the same as or similar to that described with reference to FIGS. 1 to 3, except that the second insulating layer 112 of the connection device isolation region 110B contacts the end portion of the lower surface LS of the word line structure WLS.

In the present embodiment, the first and second regions R1 and R2 may not overlap each other. For example, the first and second regions R1 and R2 may not overlap in the vertical direction (Z).

In the vertical direction (Z), the first side ss1 of the second insulating layer 112 may be located between the second side s2 of the gate contact plug 160cp1 and the end surface ES of the word line structure WLS. In another aspect, the first side ss1 of the second insulating layer 112 may not be located between the first and second sides s1, s2 of the gate contact plug 160cp1 in the vertical direction (Z).

Accordingly, the minimum distance C1 in the first direction (X) may be less than the minimum distance C2. In another aspect, the maximum distance E1 in the first direction (X) may be larger than the maximum distance E2. In another aspect, the maximum distance A1 in the first direction (X) may be greater than the maximum distance A2.

Referring to FIG. 5, a semiconductor device 100b of the modified embodiment may be the same as or similar to that described with reference to FIGS. 1 to 4, except that at least a portion of the second insulating layer 112 of the connection device isolation region 110B contacts the lower region of the end surface ES of the word line structure WLS, and the remaining portion of the second insulating layer 112 contacts the end portion of the lower surface LS of the word line structure WLS. In another aspect, in the present embodiment, at least a portion of the second insulating layer 112 may extend over a portion of the end surface ES of the word line structure WLS.

In the present embodiment, the first and second regions R1 and R2 may not overlap each other. For example, the first and second regions R1 and R2 may not overlap in the vertical direction (Z). Accordingly, the minimum distance C1 in the first direction (X) may be less than the minimum distance C2.

Compared to FIG. 2B and FIG. 4, in the present embodiment, the arrangement relationship of the first and second regions R1 and R2 may not be defined based on the end surface ES of the word line structure WLS.

From another perspective, the maximum distance A1 in the first direction (X) may be larger than the maximum distance A2.

Referring to FIG. 6, a semiconductor device 100c of the modified embodiment may be the same as or similar to that described with reference to FIGS. 1 to 5, except that the second insulating layer 112 of the connection device isolation region 110B contacts the end surface ES of the word line structure WLS and at least a portion thereof extends to the end portion of the lower surface LS of the word line structure WLS.

In the present embodiment, the connection device isolation region 110B may not include a buried insulating layer (‘113’ of FIG. 2B). For example, in an etched trench of a substrate 101 in which the connection device isolation region 110B is placed, a first insulating layer 111 may be conformally formed along the surface of the trench in sequence, and the second insulating layer 112 may be a gap-fill insulating layer that fills a space that does not fill the trench. For example, the first insulating layer 111 may define an open portion, and the second insulating layer 112 may fill the open portion as a gapfill insulating layer. The second insulating layer 112 may contact the end surface ES of the word line structure WLS as a gapfill insulating layer, and at least a portion thereof may extend onto the lower surface LS of the word line structure WLS. The first insulating layer 111 may include silicon oxide, and the second insulating layer 112 may include silicon nitride, although embodiments are not limited thereto.

In the present embodiment, the first and second regions R1 and R2 may not overlap each other. For example, the first and second regions R1 and R2 may not overlap in the vertical direction (Z). Accordingly, the minimum distance C1 in the first direction (X) may be less than the minimum distance C2. From another perspective, the maximum distance A1 in the first direction (X) may be greater than the maximum distance A2.

Similarly to what was described with reference to FIG. 5, in the present embodiment, the arrangement relationship of the first and second regions R1 and R2 may not be defined based on the end surface ES of the word line structure WLS.

Referring to FIG. 7, a semiconductor device 100d of the modified embodiment may be the same as or similar to what was described with reference to FIGS. 1 to 6, except that the gate contact plug 160cp1 includes a first portion P1 that overlaps the word line WL and a second portion P2 that does not overlap the word line WL.

At least a portion of the gate contact plug 160cp1 may be disposed to overlap the end portion EP of the word line WL in the vertical direction (Z). For example, the gate contact plug 160cp1 may include a first portion P1 that overlaps the word line WL and a second portion P2 that does not overlap the word line WL. The buried insulating layer 113 of the connection device isolation region 110B may be in contact with at least a portion of the second portion P2.

In the present embodiment, the first and second regions R1 and R2 may overlap in the vertical direction (Z).

Accordingly, the minimum distance C1 in the first direction (X) may be substantially equal to or less than the minimum distance C2. From another perspective, the maximum distance A1 in the first direction (X) may be greater than the maximum distance A2.

In the present embodiment, the arrangement relationship of the first and second regions R1 and R2 may not be defined based on the end surface ES of the word line structure WLS.

Referring to FIG. 8, a semiconductor device 100e of the modified embodiment may be the same as or similar to that described with reference to FIGS. 1 to 7, except that the second insulating layer 112 of the connection device isolation region 110B contacts the second portion P2 of the gate contact plug 160cp1 and the end surface ES of the word line structure WLS, and at least a portion thereof extends to the end portion of the lower surface LS of the word line structure WLS.

Similar to what was described with reference to FIG. 6, in the present embodiment, the connection device isolation region 110B may not include a buried insulating layer (‘113’ of FIG. 2B). For example, in an etched trench of a substrate 101 in which the connection device isolation region 110B is placed, a first insulating layer 111 may be conformally formed along a surface of the trench in sequence, and a second insulating layer 112 may be a gapfill insulating layer that fills a space that does not fill the trench. The first insulating layer 111 may include silicon oxide, and the second insulating layer 112 may include silicon nitride.

In the present embodiment, the first and second regions R1 and R2 may overlap in the vertical direction (Z).

Accordingly, the minimum distance C1 in the first direction (X) may be substantially equal to or less than the minimum distance C2. From another perspective, the maximum distance A1 in the first direction (X) may be greater than the maximum distance A2.

In this embodiment, the arrangement relationship of the first and second regions R1 and R2 may not be defined based on the end surface ES of the word line structure WLS.

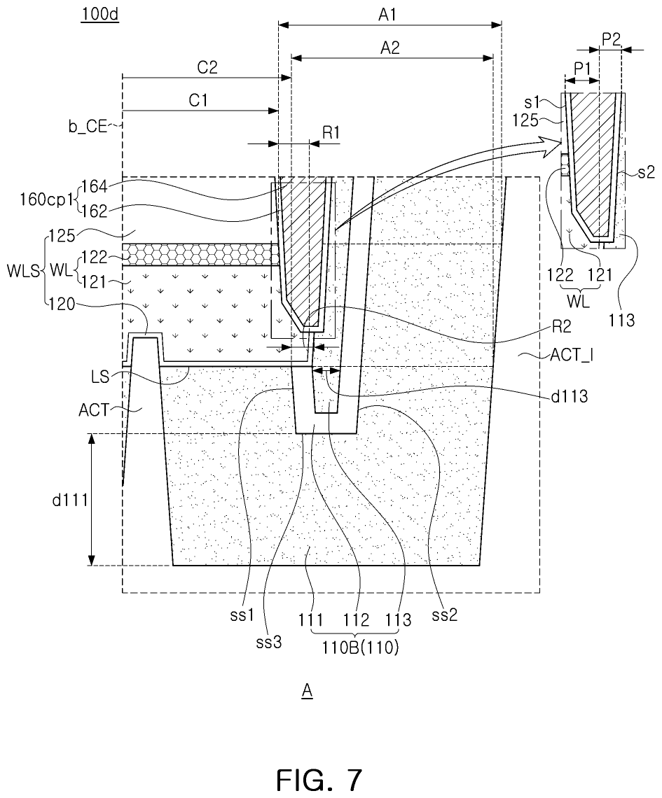

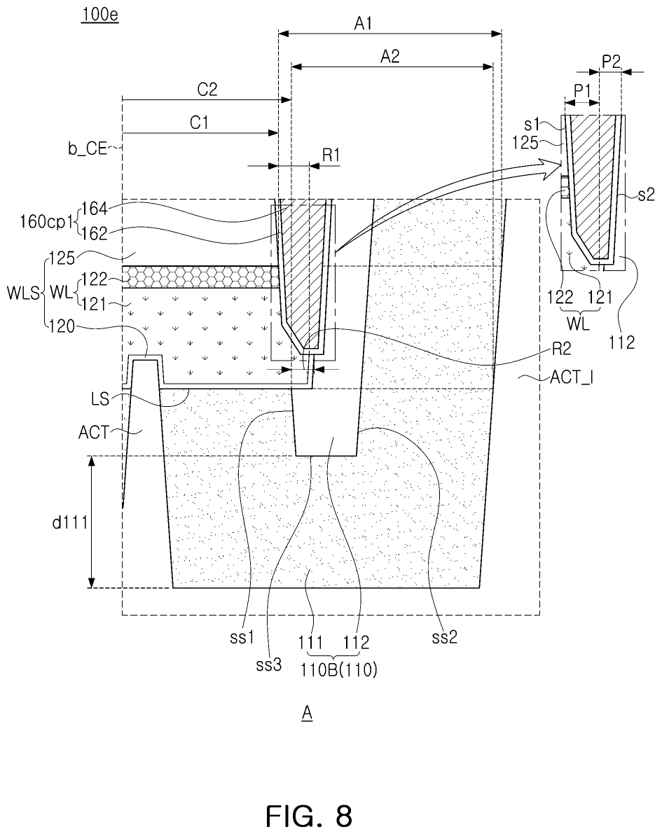

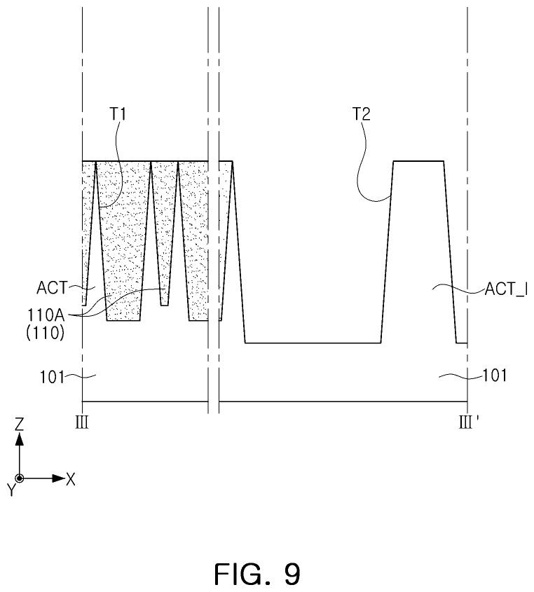

FIGS. 9, 10, 11, 12, 13, and 14 are cross-sectional views depicting intermediate processes for explaining a method of manufacturing a semiconductor device according to example embodiments.

Referring to FIGS. 1 and 9, a portion of a substrate 101 may be etched to sequentially form first element isolation trenches T1 in a cell array region CAR, second element isolation trenches T2 in a connection region IR, and third element isolation trenches (not illustrated) in a peripheral circuit region PCR. An insulating material may be deposited and buried in the first element isolation trenches T1, thereby forming a cell device isolation region 110A. A cell active region ACT may be defined by the cell device isolation region 110A. Subsequently, the insulating material deposited in the second element isolation trenches T2 and the third element isolation trenches may be removed. The above insulating material may include silicon nitride.

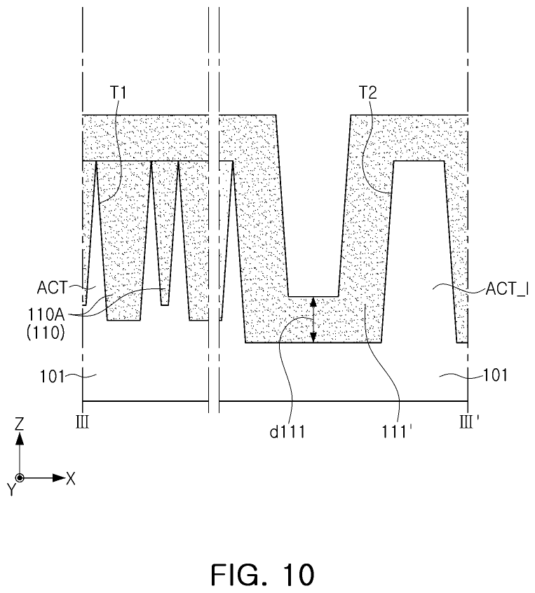

Referring to FIG. 10, a first insulating material may be deposited in the second element isolation trenches T2 to form a first insulating material layer 111′.

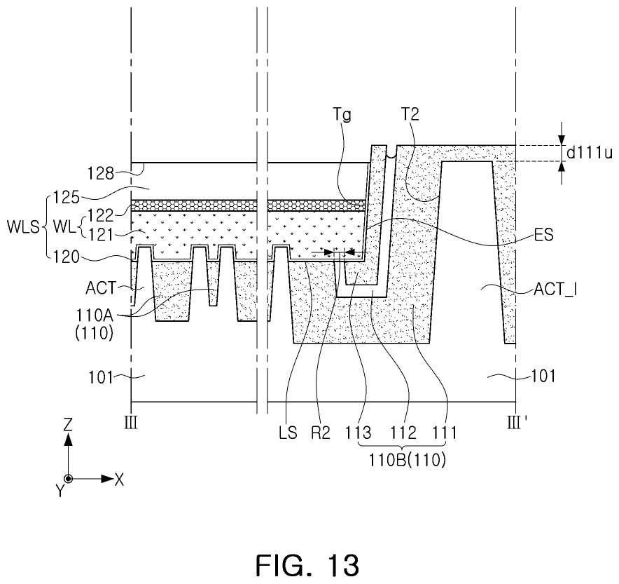

The first insulating material layer 111′ may be formed with a conformal thickness d111 along the upper surface of the cell device isolation region 110A and the surface of the second element isolation trenches T2. The thickness d111 of the first insulating material layer 111′ may be formed such that the region R2 where the second insulating layer (‘112’ of FIG. 13) and the word line structure WLS contact each other is adjacent to the end portion (or ‘end surface ES’) of the word line structure WLS.

The first insulating material may also be deposited and filled in the third trenches. The first insulating material may include silicon nitride.

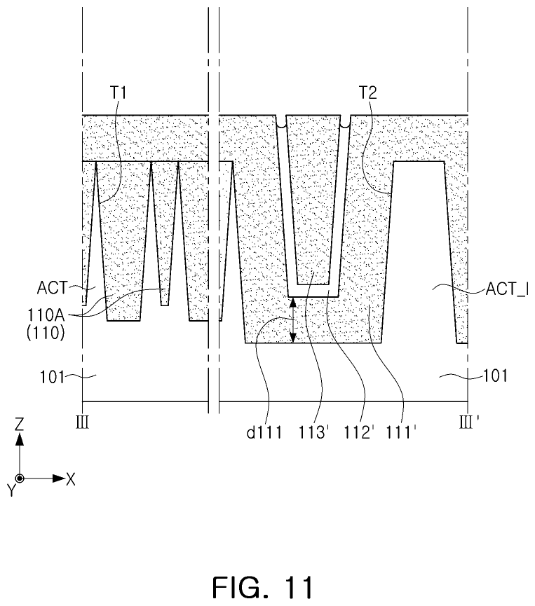

Referring to FIG. 11, a second insulating material may be deposited on a first insulating material layer 111′ to form a second insulating material layer 112′. Then, a third insulating material may be filled in the space that is not filled in the second element isolation trenches T2 to form a buried insulating layer 113′.

The second insulating material may include silicon oxide, and the third insulating material may include silicon nitride. Then, portions of the second insulating material layer 112′ and the buried insulating layer 113′ may be removed. Accordingly, the respective upper surfaces of the first insulating material layer 111′ and the buried insulating layer 113′ may be substantially at the same level (i.e., coplanar), relative to an upper surface of the substrate 101. The upper surface of the second insulating material layer 112′ may be lower than the upper surfaces of the first insulating material layer 111′ and the buried insulating layer 113′, relative to the upper surface of the substrate 101, and may have a convex shape downward.

The second insulating material may be deposited and buried on the first insulating material layer 111′ to form the second insulating layer (‘112’ of FIG. 6) or the gapfill insulating layer described with reference to FIG. 6. In this case, the third insulating material for forming the buried insulating layer 113′ described with reference to FIG. 11 may not be filled.

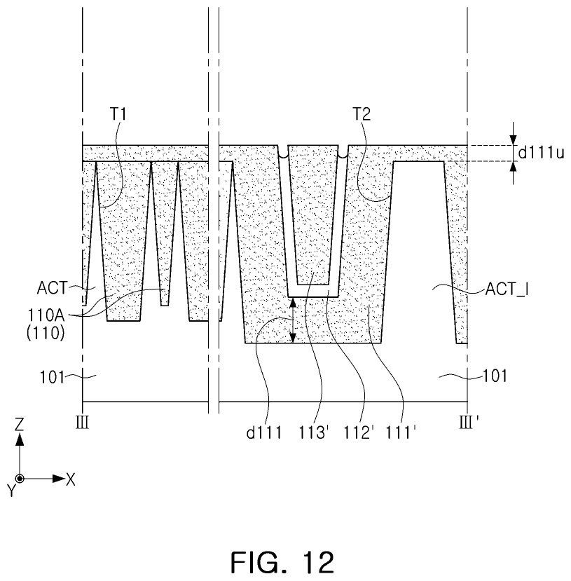

Referring to FIG. 12, portions of the first and second insulating material layers 111′ and 112′ and the buried insulating layer 113′ may be removed. Accordingly, a thickness d111u in the vertical direction (Z) of the portion extending in the first direction (X) on the active regions ACT and ACT_I, in the first insulating material layer 111′, may be thinner than the thickness d111 in the vertical direction (Z) of the portion the first insulating material layer 111′ formed on the surface of the second element isolation trenches T2.

Referring to FIG. 13, the cell active region ACT and the device isolation region 110 may be patterned to form a gate trench Tg.

The gate dielectric layer 120 may be formed with a substantially conformal thickness on the inner surface of the gate trench Tg. Subsequently, the lower pattern 121 and the upper pattern 122 of the word line WL may be formed to fill the gate trench Tg (115 in FIG. 2A), and the upper portion of the upper pattern 122 may be partially etched to form the word line WL. An insulating layer may be stacked on a substrate 101 to fill the gate trench Tg (115 in FIG. 2A) and etch the same, thereby forming a gate capping layer 125 on a word line WL. Accordingly, a word line structure WLS may be formed.

Accordingly, a connection device isolation region 110B including a first insulating layer 111, a second insulating layer 112, and a buried insulating layer 113 may be defined. An active region ACT_I may be defined by the connection device isolation region 110B. An area R2 where the second insulating layer 112 and the lower surface LS of the word line structure WLS come into contact may be defined.

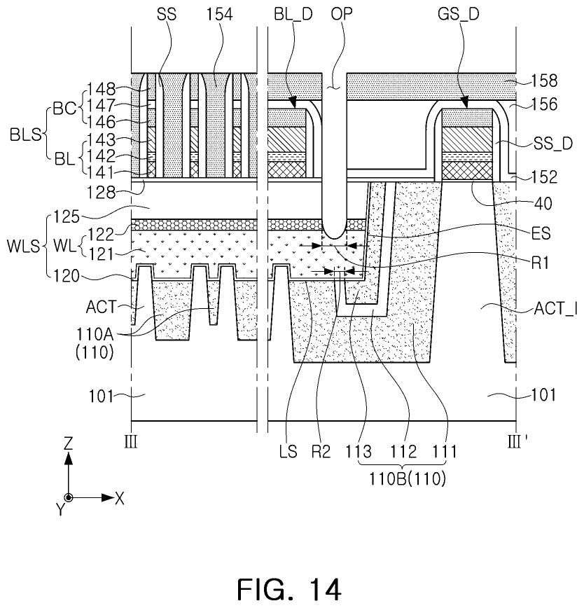

Referring to FIG. 14, bit lines BL on the cell array region CAR, dummy structures BL_D and GS_D on the connection region IR, and peripheral transistors on the peripheral circuit region PCR may be formed.

A portion of the connection device isolation region 110B at a higher level in the vertical direction (Z) than the upper surface of the word line structure WLS may be removed.

Referring also to FIG. 2A, an insulating layer and a conductive layer may be sequentially formed and patterned on the front (i.e., upper) surface of the substrate 101 to form a buffer insulating layer 128 and a first conductive pattern 141 that are sequentially stacked. The buffer insulating layer 128 may be formed of at least one of silicon oxide, silicon nitride, and silicon oxynitride. The buffer insulating layer 128 may be formed in a form where a plurality of layers are spaced apart from each other. The first conductive pattern 141 may have a shape corresponding to the planar shape of the buffer insulating layer 128. The buffer insulating layer 128 may be formed to cover the ends of two adjacent active regions ACT, for example, the adjacent second impurity regions 105b at the same time. The buffer insulating layer 128 and the first conductive pattern 141 may be used as etching masks to etch the upper portion of the device isolation region 110, the substrate 101, and the gate capping layer 125 to form a bit line contact hole 135. The bit line contact hole 135 may expose the first impurity region 105a.

Referring to FIG. 2A together, a bit line contact pattern DC filling the bit line contact hole 135 may be formed. Forming the bit line contact pattern DC may include forming a conductive layer filling the bit line contact hole 135 and performing a planarization process. As an example, the bit line contact pattern DC may be formed of polysilicon. After forming a second conductive pattern 142, a third conductive pattern 143, and first to third capping patterns 146, 147 and 148 sequentially on a first conductive pattern 141, the first to third capping patterns 146, 147 and 148 may be etched sequentially using the first to third capping patterns 146, 147 and 148 as an etching mask. As a result, a bit line structure BLS including a bit line BL including the first to third conductive patterns 141, 142 and 143 and a bit line capping pattern BC including the first to third capping patterns 146, 147 and 147 may be formed.

Referring to FIG. 2A together, a spacer structure SS may be formed on side surfaces of the bit line structure BLS. The spacer structure SS may be formed of multiple layers. Fence insulating patterns 154 may be formed between the spacer structures SS adjacent in the first direction (X). The fence insulating patterns 154 may include silicon nitride or silicon oxynitride. An anisotropic etching process using the fence insulating patterns 154 and the third capping pattern 148 as etching masks may be performed to form an opening (not illustrated) exposing the second impurity region 105b. Thereafter, a lower conductive pattern 150 and a metal-semiconductor compound layer 155 may be sequentially formed within the opening.

Referring to FIG. 2C together, peripheral transistors may be formed in the peripheral circuit region PCR. The peripheral transistors may include a peripheral gate structure GS and peripheral source/drain regions 30. A peripheral gate spacer structure SS_P may be formed on a side surface of the peripheral gate structure GS. The peripheral gate structure GS may be formed in the same process step as the formation of the bit line BL, but is not limited thereto. An insulating liner 152, a first interlayer insulating layer 156, and a second interlayer insulating layer 158 covering the peripheral transistors may be formed. Each of the insulating liner 152, the first interlayer insulating layer 156, and the second interlayer insulating layer 158 may include at least one of silicon oxide, silicon nitride, and silicon oxynitride.

Referring again to FIG. 14, a contact hole OP may be formed to expose a word line WL by penetrating the first and second interlayer insulating layers 156 and 158, the insulating liner 152, and the buffer insulating layer 128. A lower portion of the contact hole OP may expose the word line WL. Referring together with FIG. 1, the contact hole OP may be formed at an end portion EP of the word line WL. The first region R1 where the word line WL is exposed by the contact hole OP may at least partially overlap at least a portion of the second region R2 where the second insulating layer 112 and the word line structure WLS are in contact in the vertical direction (Z).

Meanwhile, on the peripheral transistors, a contact hole may be formed that penetrates the insulating liner 152 and the first and second interlayer insulating layers 156 and 158 to expose the peripheral source/drain regions 30. The contact hole on the peripheral circuit region may be formed through the same process step as the contact hole OP, for example, the same etching process.

Referring again to FIG. 1 and FIG. 2A to FIG. 2C, a contact plug 160cp1 may be formed in the contact hole OP by sequentially depositing a barrier layer 162 and a conductive layer 164. The contact plug 160cp1 and the peripheral contact plug 160cp2 may be formed simultaneously. The first upper conductive pattern 160c may be formed within the first opening. The first upper conductive pattern 160c may be formed simultaneously with the second upper conductive pattern 160p1 and the third upper conductive pattern 160p2 in the peripheral circuit region PCR. Thereafter, a patterning process may be performed on the barrier layer 162 and the conductive layer 164 to form insulating patterns 165 penetrating therethrough. Thereafter, a capacitor structure including a lower electrode, a capacitor dielectric layer, and an upper electrode may be formed on the first upper conductive pattern 160c.

As set forth above, according to some example embodiments, a semiconductor device having improved electrical characteristics and reliability is provided.

In detail, a position of a region in which a second insulating layer of a connection device isolation region and a word line structure come into contact may be adjusted by controlling a thickness of a first insulating layer of a connection device isolation region, thereby preventing a word line disconnection defect, and thereby providing a semiconductor device having improved electrical characteristics and reliability.

While example embodiments have been illustrated and described above, it will be apparent to those skilled in the art that modifications and variations could be made without departing from the scope of the present inventive concept as defined by the appended claims.

What is claimed is:

1. A semiconductor device, comprising:
a substrate having a cell array region, a peripheral circuit region, and a connection region between the cell array region and the peripheral circuit region;
a device isolation region including a cell device isolation region defining a cell active region on the cell array region and a connection device isolation region defining an active region on the connection region, on the substrate;
a gate structure extending, in a first direction parallel to an upper surface of the substrate, across the cell active region on the cell array region and comprising a gate electrode extending in the first direction into the connection device isolation region of the device isolation region on the connection region; and
a gate contact plug electrically connected to the gate electrode, on the connection region, the gate contact plug having a first side facing the cell array region and a second side opposite the first side,
wherein the connection device isolation region comprises a first insulating layer and a second insulating layer on the first insulating layer,
wherein the second insulating layer has a first side facing the cell array region and a second side facing the peripheral circuit region, and
wherein a minimum distance between the cell array region and the first side of the gate contact plug is substantially equal to or less than a minimum distance between the cell array region and the first side of the second insulating layer in the first direction.

2. The semiconductor device of claim 1, wherein the connection device isolation region further comprises a buried insulating layer on the second insulating layer, and
wherein the buried insulating layer contacts at least a portion of an end surface of the gate structure.

3. The semiconductor device of claim 2, wherein at least a portion of the buried insulating layer extends onto a lower surface of the gate structure.

4. The semiconductor device of claim 3, wherein the second insulating layer contacts at least a portion of the lower surface of the gate structure, and
the first side of the second insulating layer is positioned between the first side and the second side of the gate contact plug, in a vertical direction perpendicular to the upper surface of the substrate.

5. The semiconductor device of claim 2, wherein the second insulating layer contacts an end portion of a lower surface of the gate structure.

6. The semiconductor device of claim 5, wherein at least a portion of the second insulating layer extends onto a portion of the end surface of the gate structure.

7. The semiconductor device of claim 5, wherein the first side of the second insulating layer is between the second side of the gate contact plug and an end surface of the gate structure, in a vertical direction.

8. The semiconductor device of claim 1, wherein the first insulating layer defines an open portion, and the second insulating layer is a gapfill insulating layer at least partially filling the open portion,
wherein the gapfill insulating layer contacts at least a portion of an end surface of the gate structure.

9. The semiconductor device of claim 8, wherein at least a portion of the gapfill insulating layer extends onto a lower surface of the gate structure.

10. The semiconductor device of claim 1, wherein the gate contact plug includes a first portion overlapping the gate electrode in a vertical direction perpendicular to the upper surface of the substrate and a second portion not overlapping the gate electrode in the vertical direction.

11. The semiconductor device of claim 10, wherein the second portion of the gate contact plug contacts the second insulating layer.

12. The semiconductor device of claim 1, wherein a lower surface of the connection device isolation region is at a lower level than a lower surface of the cell device isolation region, relative to the upper surface of the substrate.

13. The semiconductor device of claim 1, wherein the second insulating layer further comprises a lower surface connecting each end of the first and second sides of the second insulating layer, and
wherein the lower surface of the second insulating layer is at a higher level than a lower surface of the cell device isolation region, relative to the upper surface of the substrate.

14. A semiconductor device, comprising:
a device isolation region defining a cell active region and a peripheral active region on a substrate;
a gate structure extending across the cell active region in a horizontal direction parallel to an upper surface of the substrate, extending into the device isolation region, and having an end surface within the device isolation region; and
a gate contact plug contacting the gate structure between the cell active region and the peripheral active region,
wherein a device isolation layer of the device isolation region comprises a first insulating layer, a second insulating layer on the first insulating layer, and a buried insulating layer on the second insulating layer, and
a maximum distance in the horizontal direction, between the end surface and a first portion on which the gate contact plug and the gate structure contact each other is substantially equal to or greater than a maximum distance in the horizontal direction between the end surface and a second portion on which the second insulating layer of the device isolation layer contacts the gate structure.

15. The semiconductor device of claim 14, wherein a lower surface of the gate structure comprises:
a first portion in contact with the first insulating layer; and
a second portion in contact with the buried insulating layer,
wherein a width of the first portion in the horizontal direction is greater than a width of the second portion in the horizontal direction.

16. The semiconductor device of claim 14, wherein the device isolation region defines an open portion, and the first insulating layer extends to have a first thickness along a surface of the open portion, and
a maximum thickness of the buried insulating layer in the horizontal direction is less than the first thickness.

17. The semiconductor device of claim 14, wherein the first insulating layer and the buried insulating layer comprise silicon oxide, and
wherein the second insulating layer comprises silicon nitride.

18. The semiconductor device of claim 14, wherein the gate structure includes a gate electrode, and
wherein the gate electrode comprises:
a lower pattern comprising at least one of a metal or a metal nitride; and
an upper pattern on the lower pattern and including a doped semiconductor material.

19. A semiconductor device, comprising:
a substrate having a cell array region, a peripheral circuit region, and a connection region between the cell array region and the peripheral circuit region;
a device isolation region including a cell device isolation region defining a cell active region of the cell array region and a connection device isolation region defining an active region on the connection region, on the substrate;
a gate structure extending across the cell active region, on the cell array region, in a first direction parallel to an upper surface of the substrate, and including a gate electrode extending into the connection device isolation region of the device isolation region on the connection region; and
a gate contact plug electrically connected to the gate electrode, on the connection region,
wherein the connection device isolation region comprises a first insulating layer, a second insulating layer on the first insulating layer, and a buried insulating layer on the second insulating layer, and
wherein a maximum distance in the first direction between the active region on the connection region and a first portion on which the gate contact plug contacts the gate electrode is substantially equal to or greater than a maximum distance in the first direction between the active region on the connection region and a second portion on which the second insulating layer contacts the gate electrode.

20. The semiconductor device of claim 19, wherein the active region on the connection region extends in a second direction parallel to the upper surface of the substrate and perpendicular to the first direction in which the gate electrode extends, and contacts the connection device isolation region, and
an upper surface of the active region on the connection region is at substantially the same level as an uppermost surface of each of the second insulating layer and the buried insulating layer, relative to the upper surface of the substrate.
